(19) United States
(12) Patent Application Publication
(10) Pub. No.: US 2013/0074908 A1
(43) Pub. Date: Mar. 28, 2013

(54) ORGANIC THIN-FILM SOLAR CELL MODULE

(71) Applicant: Hiroyuki Suzuki, Tokyo-to (JP)

(72) Inventor: Hiroyuki Suzuki, Tokyo-to (JP)

(73) Assignee: DAI NIPPON PRINTING CO., LTD., Tokyo-to (JP)

(21) Appl. No.: 13/701,929

(22) PCT Filed: Mar. 16, 2011
(86) PCT No.: PCT/JP2011/056268

§ 371 Date: Dec. 4, 2012

(30) Foreign Application Priority Data
Jun. 23, 2010 (JP) 2010-142990

(51) Int. Cl. H01L 27/30

(52) U.S. Cl. CPC H01L 27/302
USPC 136/249

(57) ABSTRACT

An organic thin-film solar cell module comprising a substrate, a first electrode layer formed on the substrate, a photoelectric conversion layer formed in a pattern on the first electrode layer and including different types of photoelectric conversion parts having different absorption wavelength ranges, a second electrode layer formed so as to cover the photoelectric conversion layer, and an insulating layer formed in a pattern between the first and second electrode layers and arranged between the photoelectric conversion parts, whereby a buffer layer or layers are formed, depending on the type of the photoelectric conversion part, in the position between the photoelectric conversion parts and the first or second electrode layer.

### TECHNICAL FIELD

The invention relates to an organic thin-film solar cell module having design characteristics.

### BACKGROUND ART

Alight receiving surface of a conventional solar battery generally has a single color. Recently, as solar cell modules have been developed actively, approaches to provide them with design characteristics have been made by allowing them to show letters, symbols, figures, patterns or the like for a purpose such as an improvement in design characteristics or harmony with landscape.

For example, a technique to provide a dye-sensitized solar cell module with design characteristics is disclosed, which includes forming porous oxide semiconductor layers each carrying different dyes to form unit solar cell elements each having two or more colors, and mosaically arranging the unit solar cell elements each having two or more colors to form a specific letter, symbol, or figure pattern (see Patent Literature 1).

### CITATION LIST

### Patent Literature

Patent Literature 1: Japanese Patent Application Publication (JP-A) No. 2006-179380

### SUMMARY OF INVENTION

### Technical Problem

An organic thin-film solar cell module having good design characteristics can be produced by a process including forming, on a single substrate, different types of photoelectric conversion layers using different organic materials having different absorption wavelength ranges and arranging the different types of photoelectric conversion layers in such a manner that an arbitrary pattern such as a letter, a symbol, a graph, or a figure is displayed.

Such an organic thin-film solar cell module comprises different types of photoelectric conversion layers arranged two-dimensionally between opposite electrodes on a single substrate, which can be considered to be an equivalent circuit having different types of solar cells connected in parallel. These solar cells have different current-voltage characteristics because the respective photoelectric conversion layers are made of organic materials with different oxidation-reduction potentials.

A solar cell has its own current-voltage characteristics, in which the current and voltage coordinate values on the current-voltage characteristic curve, where the voltage/current value is equal to the external load resistance, serve as the driving current and the driving voltage, respectively. In the case of an organic thin-film solar cell, in a solar cell module having a plurality of solar cells connected in parallel, the voltage coordinate value on the current-voltage characteristic curve of the solar cell module, where the current/voltage value is equal to the external load resistance, serves as the operating voltage of the solar cell module. The current coordinate value of a point on the current-voltage characteristic curve of each solar cell at the operating voltage of the solar cell module corresponds to the operating current of each solar cell. Thus, when solar cells with different current-voltage characteristics are connected in parallel, the solar cells with different current-voltage characteristics have different operating currents at the operating voltage of the solar cell module applied to the same external load resistance.

Thus, when solar cells with different current-voltage characteristics are connected in parallel, the different operating currents of the solar cells at the operating voltage of the solar cell module applied to a certain external resistance may cause a problem in that the current flows in the forward direction through a certain type of solar cells, but in the reverse direction through another type of solar cells. In this case, solar cells through which the current flows in the reverse direction cause a problem in that the operating current of solar cells through which the current flows in the forward direction is reduced so that the output characteristics of the whole of the solar cell module is degraded. The current flowing in the reverse direction may also cause generation of heat or fire, or lead to short circuit destruction.

When solar cells with different current-voltage characteristics are connected in parallel, the different operating currents of the solar cells may cause a significant reduction in the output of a certain type of solar cells at the operating voltage of the solar cell module applied to a certain external resistance. This causes a problem in that the total output of all solar cells is reduced so that the output characteristics of the whole of the solar cell module are degraded. In addition, it is often very difficult to operate a solar cell module in such a manner that all solar cells have high output.

Solar cells with different current-voltage characteristics connected in parallel also have a problem in that they interfere with one another so that the solar cell performance can be degraded.

A main object of the invention, which has been accomplished in view of the above problems, is to provide an organic thin-film solar cell module that has a plurality of types of photoelectric conversion layers with different absorption wavelength ranges for improving design characteristics and can offer stable, high, solar cell performance.

### Solution to Problem

To achieve the object, the invention provides an organic thin-film solar cell module, comprising: a substrate; a first electrode layer formed on the substrate; a photoelectric conversion layer formed in a pattern on the first electrode layer and including different types of photoelectric conversion parts having different absorption wavelength ranges; a second electrode layer formed so as to cover the photoelectric conversion layer; and an insulating layer formed in a pattern between the first electrode layer and the second electrode layer and arranged between the photoelectric conversion parts, characterized in that a buffer layer or buffer layers are formed, depending on a type of the photoelectric conversion part, in at least one of the position between the photoelectric conversion parts and the first electrode layer and the position between the photoelectric conversion parts and the second electrode layer.

According to the invention, different types of photoelectric conversion parts having different absorption wavelength ranges are provided, which can be arranged to show an arbitrary pattern, such as letters, symbols, graphics, or figures, so that good design characteristics can be provided. According to the invention, assuming that a region having a single photoelectric conversion part is a single solar cell, a specific buffer layer formed depending on the type of the photoelectric conversion part can control the current-voltage characteristics of a solar cell. This makes it possible to prevent current through all solar cells from flowing in the reverse direction or to make the total output of all solar cells higher, at the operating voltage of the organic thin-film solar cell module applied to a certain external resistance. In addition, solar cells with different current-voltage characteristics can be prevented from interfering with one another, so that degradation of the solar cell performance can be prevented, which makes it possible for solar cells to have stable characteristics.

In the invention, the buffer layers containing different materials that vary depending on the types of the photoelectric conversion parts may be formed. This makes it possible to control the current-voltage characteristics of each solar cell based on the difference between the materials of the buffer layers, so that current through all solar cells can be prevented from flowing in the reverse direction or the total output of all solar cells can be made higher, at the operating voltage of the organic thin-film solar cell module applied to a certain external resistance.

In the invention, buffer layer may not be formed on one type of the photoelectric conversion part, and the buffer layer may be formed on another type of the photoelectric conversion part. This makes it possible to control the current-voltage characteristics of the solar cell based on the presence or absence of the buffer layer formed, so that current through all solar cells can be prevented from flowing in the reverse direction or the total output of all solar cells can be made higher, at the operating voltage of the organic thin-film solar cell module applied to a certain external resistance.

In the invention, assuming that a region having one of the photoelectric conversion parts is a single solar cell, the buffer layer preferably contains a material capable of making the open circuit voltage of the solar cell lower than the open circuit voltage of a reference solar cell having only the photoelectric conversion part sandwiched between the first electrode layer and the second electrode layer. This makes the selection of the material for the buffer layer easy.

### Advantageous Effects of Invention

The invention can advantageously provide a multi-functional organic thin-film solar cell module having good design characteristics and various display functions that can be used for advertising or marketing purposes. The invention is also advantageous in that the organic thin-film solar cell module having a photoelectric conversion layer including different types of photoelectric conversion parts with different absorption wavelength ranges can have stable solar cell characteristics.

### BRIEF DESCRIPTION OF DRAWINGS

FIGS. 1A and 1B are schematic plan and cross-sectional views showing an example of the organic thin-film solar cell module of the invention.

FIG. 2 is a schematic plan view showing an example of the first electrode layer in the organic thin-film solar cell module of the invention.

FIG. 3 is a schematic plan view showing an example of the insulating layer in the organic thin-film solar cell module of the invention.

FIG. 4 is a schematic plan view showing an example of the photoelectric conversion layer in the organic thin-film solar cell module of the invention.

FIG. 5 is a schematic plan view showing an example of the buffer layer in the organic thin-film solar cell module of the invention.

FIGS. 6A and 6B are schematic plan and cross-sectional views showing another example of the organic thin-film solar cell module of the invention.

FIGS. 7A to 7D are each a schematic plan view showing other examples of the first electrode layer, the insulating layer, the photoelectric conversion layer, and the buffer layer in the organic thin-film solar cell module of the invention.

FIG. 8 is a schematic cross-sectional view showing a further example of the organic thin-film solar cell module of the invention.

FIG. 9 is a schematic cross-sectional view showing a further example of the organic thin-film solar cell module of the invention.

FIG. 10 is a schematic cross-sectional view showing a further example of the organic thin-film solar cell module of the invention.

FIGS. 11A to 11C are each a schematic cross-sectional view for illustrating a further example of the organic thin-film solar cell module of the invention.

FIGS. 12A and 12B are each a graph showing an example of the current-voltage characteristics of the organic thin-film solar cell module of the invention.

FIGS. 13A and 13B are each a graph showing another example of the current-voltage characteristics of the organic thin-film solar cell module of the invention.

FIG. 14 is a schematic cross-sectional view showing a further example of the organic thin-film solar cell module of the invention.

### DESCRIPTION OF EMBODIMENTS

Hereinafter, the organic thin-film solar cell module of the invention is described in detail.

The organic thin-film solar cell module of the invention comprises: a substrate, a first electrode layer formed on the substrate, a photoelectric conversion layer formed in a pattern on the first electrode layer and including different types of photoelectric conversion parts having different absorption wavelength ranges, a second electrode layer formed so as to cover the photoelectric conversion layer, and an insulating layer formed in a pattern between the first and second electrode layers and arranged between the photoelectric conversion parts, characterized in that a buffer layer buffer or layers are formed, depending on the type of the photoelectric conversion part, in at least one of the position between the photoelectric conversion parts and the first electrode layer and the position between the photoelectric conversion parts and the second electrode layer.

The organic thin-film solar cell module of the invention is described with reference to the drawings.

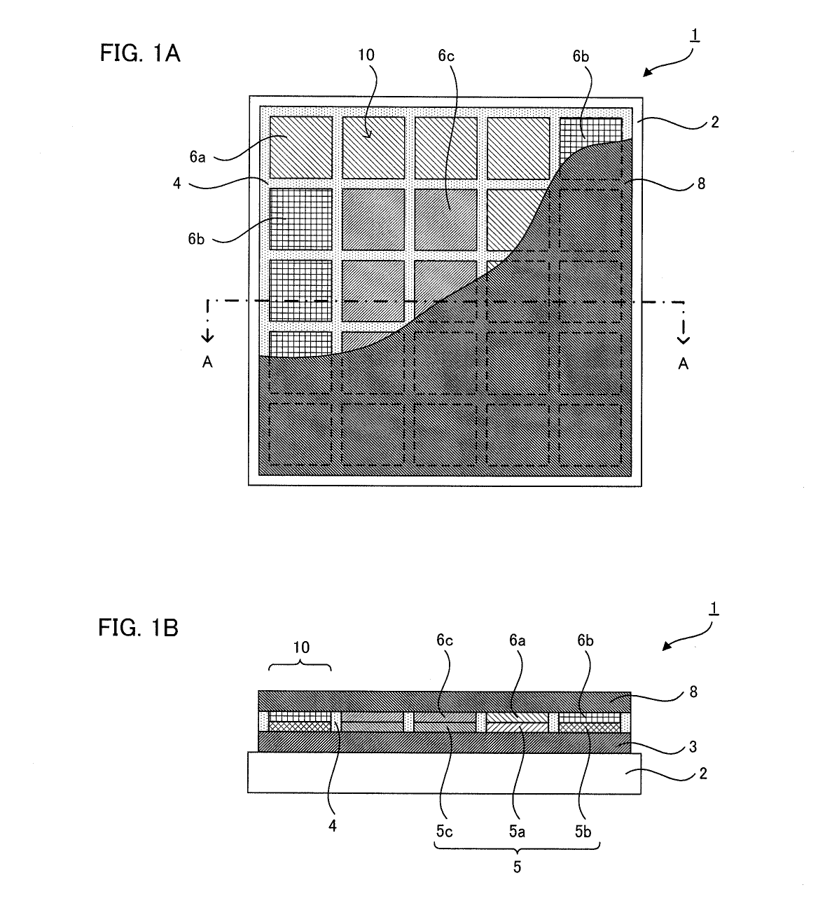

FIGS. 1A and 1B are schematic plan and cross-sectional views, respectively, showing an example of the organic thin-film solar cell module of the invention, in which FIG. 1B is a cross-sectional view along line A-A of FIG. 1A.

As shown in FIGS. 1A and 1B, an organic thin-film solar cell module 1 comprises: a substrate 2, a first electrode layer 3 formed on the substrate 2, an insulating layer 4 formed in a lattice pattern on the first electrode layer 3 and having openings, a photoelectric conversion layer 5 formed in a pattern on the first electrode layer 3 and including different types of photoelectric conversion parts (5a, 5b, 5c) having different absorption wavelength ranges and arranged in the openings of the insulating layer 4, respectively, buffer layers (6a, 6b, 6c) formed on the photoelectric conversion parts (5a, 5b, 5c), respectively, and containing different materials that vary depending on the types of the photoelectric conversion parts (5a, 5b, 5c), and a second electrode layer 8 formed on the buffer layers (6a, 6b, 6c) and the insulating layer 4. In FIG. 1A, part of the second electrode layer is omitted, and parts of the buffer layers are indicated by dashed lines.

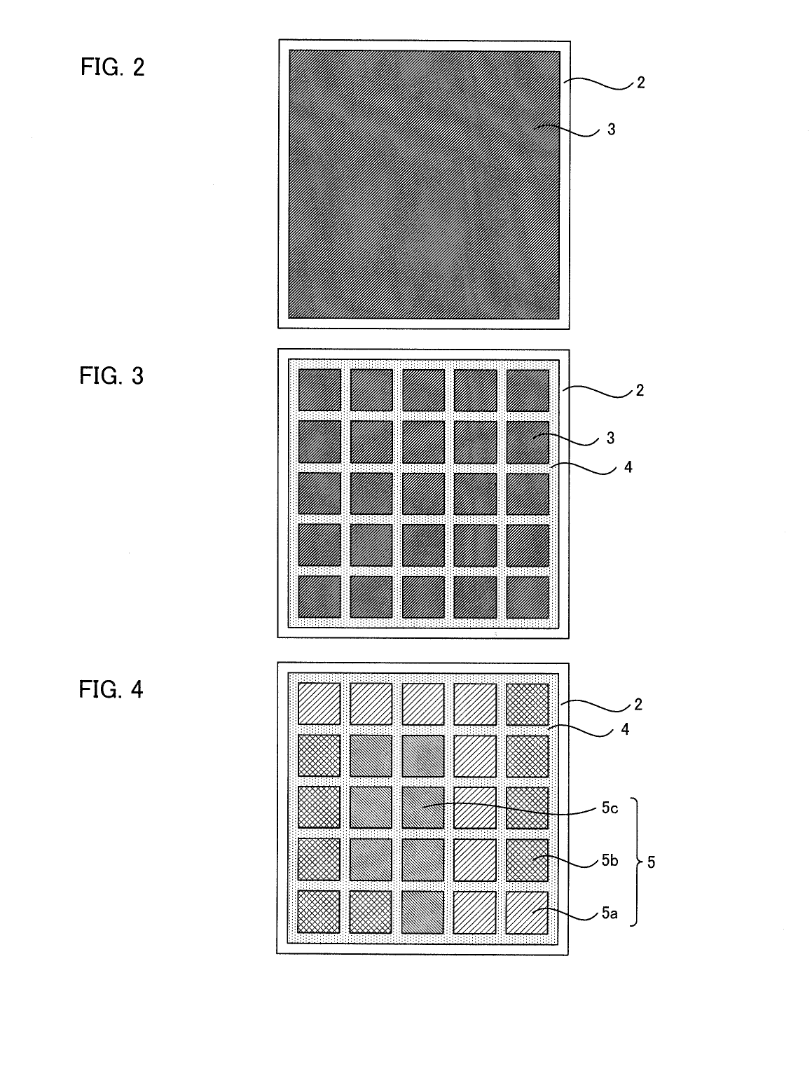

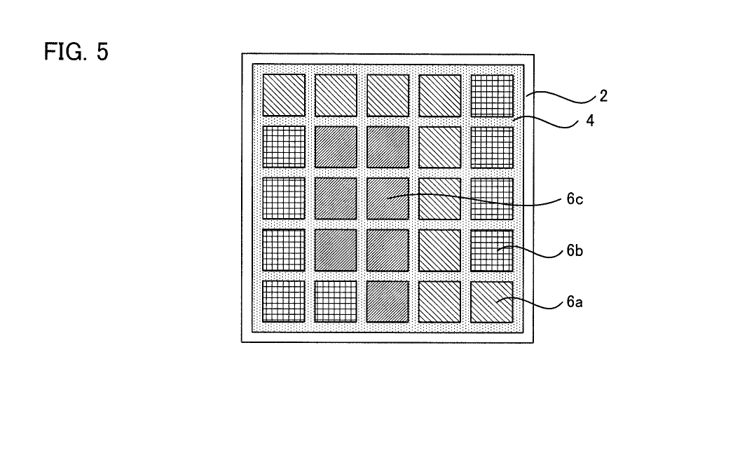

FIGS. 2 to 5 are schematic plan views showing the respective components of the organic thin-film solar cell module 1 shown in FIGS. 1A and 1B.

As shown in FIG. 2, the first electrode layer 3 is formed all over the substrate 2. As shown in FIG. 1A, the second electrode layer 8 is also formed all over the photoelectric conversion layer 5 and the buffer layers (6a, 6b, 6c). As shown in FIG. 3, the insulating layer 4 is formed in a lattice pattern on the first electrode layer 3, and as shown in FIG. 1B, the insulating layer 4 insulates the first and second electrode layers 3 and 8 from each other.

As shown in FIG. 4, the photoelectric conversion layer comprises three types of parts having different absorption wavelength ranges: first photoelectric conversion parts 5a, second photoelectric conversion parts 5b, and third photoelectric conversion parts 5c. Each type of photoelectric conversion parts (5a, 5b, 5c) are regularly arranged, and first, second, and third photoelectric conversion parts 5a, 5b, and 5c are arranged to show an arbitrary pattern.

As shown in each of FIGS. 1B, 4, and 5, the buffer layers (6a, 6b, 6c) are formed on the photoelectric conversion parts (5a, 5b, 5c), respectively, and the buffer layers (6a, 6b, 6c) contain different materials that vary depending on the types of the photoelectric conversion parts (5a, 5b, 5c). The first photoelectric conversion part-specific buffer layer 6a is formed on the first photoelectric conversion part 5a. The second photoelectric conversion part-specific buffer layer 6b is formed on the second photoelectric conversion part 5b. The third photoelectric conversion part-specific buffer layer 6c is formed on the third photoelectric conversion part 5c. The materials for these buffer layers (6a, 6b, 6c) are selected depending on the type of the photoelectric conversion part (5a, 5b, 5c).

In the organic thin-film solar cell module 1 shown in FIGS. 1A and 1B, when the substrate 2 and the first electrode layer 3 are transparent, the light-receiving surface may be on the substrate 2 side, and when the second electrode layer 8 is transparent, the light-receiving surface may be on the second electrode layer 8 side. As shown in FIG. 4, different types of photoelectric conversion parts (5a, 5b, 5c) form an arbitrary pattern, which can be displayed on the light-receiving surface, so that a colorful organic thin-film solar cell module can be provided. When both of the substrate 2 and the first and second electrode layers 3 and 8 are transparent, a colorful, see-through, organic thin-film solar cell module can be provided.

Depending on the type of the photoelectric conversion parts (5a, 5b, 5c), each specific buffer layer (6a, 6b, 6c) is stacked on each corresponding photoelectric conversion part (5a, 5b, 5c). Thus, assuming that a region having a single photoelectric conversion part (5a, 5b, or 5c) is a single solar cell 10, the current-voltage characteristics of each solar cell 10 can be controlled using each buffer layer (6a, 6b, 6c). Thus, when the operating voltage of the organic thin-film solar cell module is applied to a certain external resistance, current through all solar cells can be prevented from flowing in the reverse direction, or the total output of all solar cells can be made higher. In addition, solar cells with different current-voltage characteristics can be prevented from interfering with one another so that degradation of solar cell performance can be prevented.

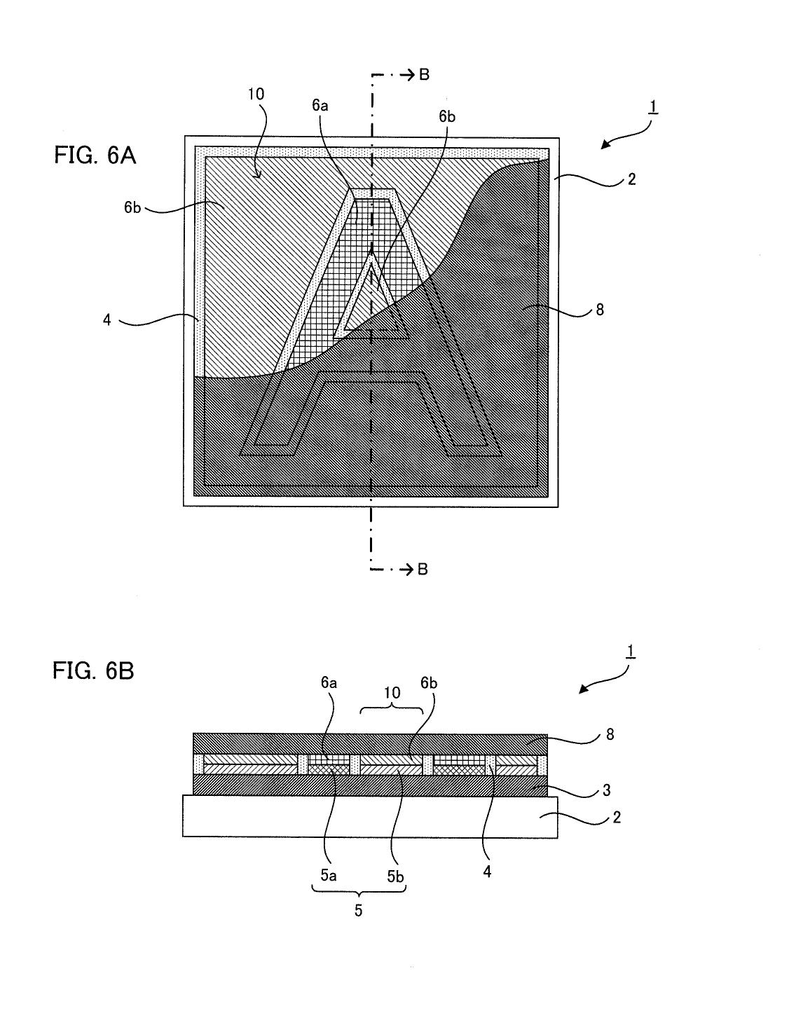

FIGS. 6A and 6B are schematic plan and cross-sectional views, respectively, showing another example of the organic thin-film solar cell module of the invention, in which FIG. 6B is a cross-sectional view along line B-B of FIG. 6A. As shown in FIGS. 6A and 6B, an organic thin-film solar cell module 1 comprises: a substrate 2; a first electrode layer 3 formed on the substrate 2; an insulating layer 4 formed in a pattern on the first electrode layer 3 and having openings; a photoelectric conversion layer 5 formed in a pattern on the first electrode layer 3 and including different types of photoelectric conversion parts (5a, 5b) having different absorption wavelength ranges and arranged in the openings of the insulating layer 4, respectively; buffer layers (6a, 6b) formed on the photoelectric conversion parts (5a, 5b), respectively, and containing different materials that vary depending on the types of the photoelectric conversion parts (5a, 5b); and a second electrode layer 8 formed on the buffer layers (6a, 6b) and the insulating layer 4. In FIG. 6A, part of the second electrode layer is omitted, and parts of the buffer layers are indicated by dashed lines.

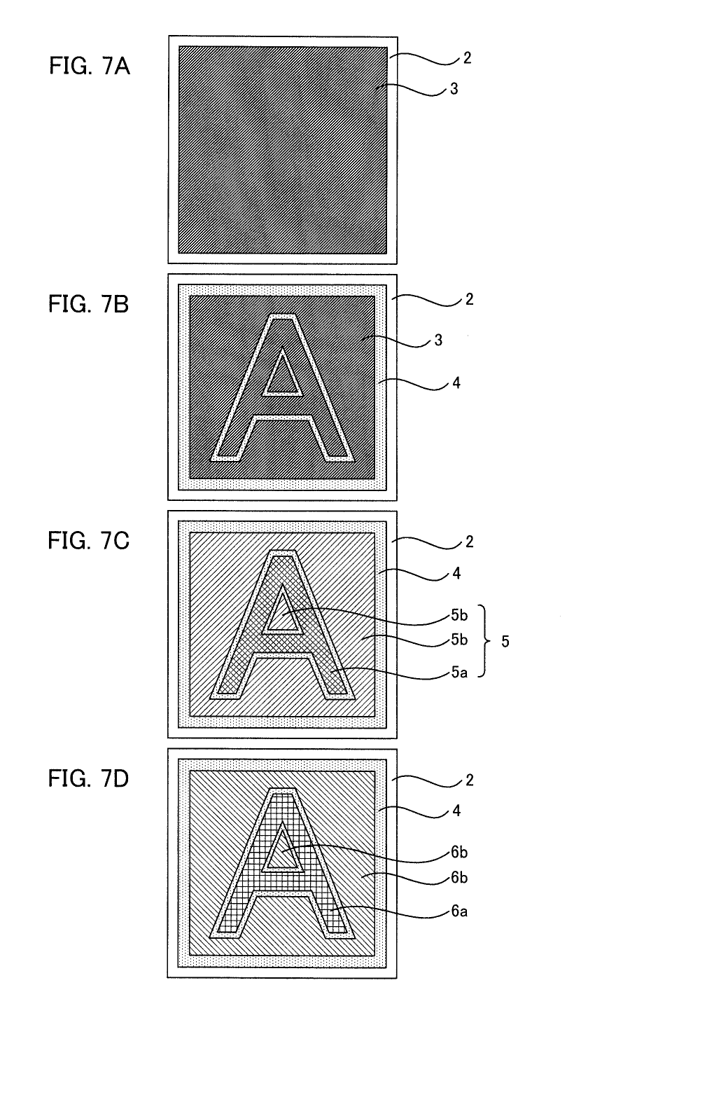

FIGS. 7A to 7D are schematic plan views showing the respective components of the organic thin-film solar cell module 1 shown in FIGS. 6A and 6B.

As shown in FIG. 7A, the first electrode layer 3 is formed all over the substrate 2. As shown in FIG. 6A, the second electrode layer 8 is also formed all over so as to cover the photoelectric conversion layer 5 and the buffer layers (6a, 6b). As shown in FIG. 7B, the insulating layer 4 is formed in a pattern on the first electrode layer 3, and as shown in FIG. 6B, the insulating layer 4 insulates the first and second electrode layers 3 and 8 from each other.

As shown in FIG. 7C, the photoelectric conversion layer 5 includes two types of parts having different absorption wavelength ranges: first photoelectric conversion parts 5a and second photoelectric conversion parts 5b. The first and second photoelectric conversion parts 5a and 5b are arranged to show the letter “A.”

As shown in each of FIGS. 6B and 7C and 7D, the buffer layers (6a, 6b) are formed on the photoelectric conversion parts (5a, 5b), respectively, and the buffer layers (6a, 6b) contain different materials that vary depending on the types of the photoelectric conversion parts (5a, 5b). The first photoelectric conversion part-specific buffer layer 6a is formed on the first photoelectric conversion part 5a. The second photoelectric conversion part-specific buffer layer 6b is formed on the second photoelectric conversion part 5b. The materials for these buffer layers (6a, 6b) are selected depending on the type of the photoelectric conversion part (5a, 5b).

In the organic thin-film solar cell module 1 shown in each of FIGS. 6A and 6B, when the substrate 2 and the first electrode layer 3 are transparent, the light-receiving surface may be on the substrate 2 side, and when the second electrode layer 8 is transparent, the light-receiving surface may be on the second electrode layer 8 side. As shown in FIG. 7(c), the letter “A” can be colorfully displayed on the light-receiving surface. When both of the substrate 2 and the first and second electrode layers 3 and 8 are transparent, a colorful, see-through, organic thin-film solar cell module can be provided.

Depending on the type of the photoelectric conversion part (5a, 5b), each specific buffer layer (6a, 6b) is stacked on each corresponding photoelectric conversion part (5a, 5b). Thus, assuming that a region having a single photoelectric conversion part (5a or 5b) is a single solar cell 10, the current-voltage characteristics of each solar cell 10 can be controlled using each buffer layer (6a, 6b). Thus, when the operating voltage of the organic thin-film solar cell module is applied to a certain external resistance, current through all solar cells can be prevented from flowing in the reverse direction, or the total output of all solar cells can be made higher. In addition, solar cells with different current-voltage characteristics can be prevented from interfering with one another so that degradation of solar cell performance can be prevented.

As described above, according to the invention, different types of photoelectric conversion parts having different absorption wavelength ranges can be arranged to show an arbitrary pattern, such as letters, symbols, graphics, or figures. Thus, the arbitrary pattern, such as letters, symbols, graphics, or figures, can be colorfully displayed on the light-receiving surface. This makes it possible to provide a colorful, organic thin-film solar cell module having a display function and good design characteristics.

In addition, each specific buffer layer is stacked depending on the type of the photoelectric conversion part, so that the current-voltage characteristics of the solar cell can be controlled using the buffer layer. Thus, when the operating voltage of the organic thin-film solar cell module is applied to a certain external resistance, current through all solar cells can be prevented from flowing in the reverse direction or the total output of all solar cells can be made higher, so that the organic thin-film solar cell module can have improved output characteristics. In addition, solar cells with different current-voltage characteristics can be prevented from interfering with one another so that degradation of solar cell performance can be prevented, which makes it possible to keep the solar cell characteristics stable. The organic thin-film solar cell module can also have reliable safety.

The term “assuming that a region having a single photoelectric conversion part is a single solar cell” is based on the following. The organic thin-film solar cell module of the invention comprises a plurality of photoelectric conversion parts arranged two-dimensionally, which may be considered to be an equivalent circuit having a plurality of solar cells connected in parallel. Thus, a region having a single photoelectric conversion part can be assumed to be a single solar cell.

For example, the organic thin-film solar cell module 1 shown in FIGS. 1A and 1B may be considered to be an equivalent circuit having 25 solar cells 10 connected in parallel. The organic thin-film solar cell module 1 shown in FIGS. 6A and 6B may be considered to be an equivalent circuit having three solar cells 10 connected in parallel.

Hereinafter, each component of the organic thin-film solar cell module of the invention is described.

1. Buffer Layer

In the invention, the buffer layer is formed, depending on the type of the photoelectric conversion part, in at least one of the position between the photoelectric conversion parts and the first electrode layer and the position between the photoelectric conversion parts and the second electrode layer.

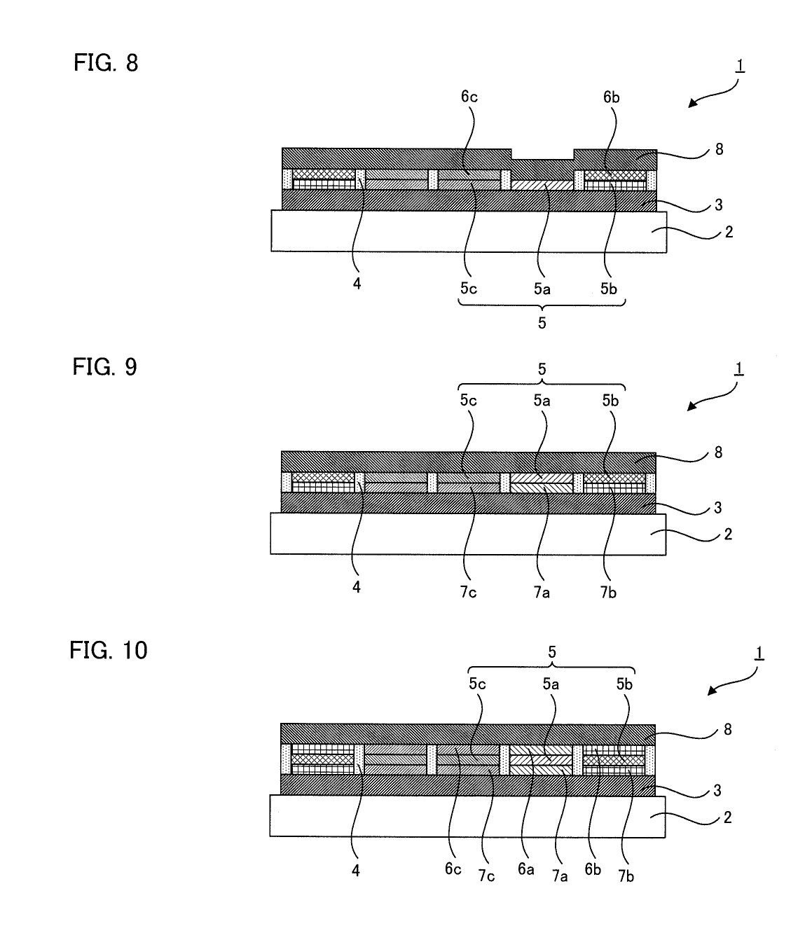

The buffer layer or layers may be formed and arranged depending on the type of the photoelectric conversion part. For example, buffer layers may be formed on all types of photoelectric conversion parts, or buffer layer may not be formed on one type of photoelectric conversion part or parts, while a buffer layer or layers may be formed on any other type or types of photoelectric conversion layer or layers. Specifically, FIG. 1B shows that buffer layers (6a, 6b, 6c) are formed on all types of photoelectric conversion parts (5a, 5b, 5c). FIG. 8 shows that buffer layers (6G, 6B) are formed on second and third photoelectric conversion parts 5b and 5c, respectively, while buffer layer is not formed on a first photoelectric conversion part 5a.

If buffer layers are formed on all types of photoelectric conversion parts, the buffer layers may contain different materials that vary depending on the types of the photoelectric conversion parts, so that the current-voltage characteristics of each solar cell can be controlled based on the difference between the materials of the buffer layers. If buffer layers are formed on all types of photoelectric conversion parts, the buffer layers may have different thicknesses that vary depending on the types of the photoelectric conversion parts, so that the current-voltage characteristics of each solar cell can be controlled based on the difference between the thicknesses of the buffer layers.

If no buffer layer is formed on a type of photoelectric conversion part and a buffer layer or layers are formed on any other type or types of photoelectric conversion parts, the current-voltage characteristics of the solar cell can be controlled based on the presence or absence of the buffer layer formed.

The position where the buffer layer is formed may be as follows. The buffer layer may be formed in at least one of the position between the photoelectric conversion parts and the first electrode layer and the position between the photoelectric conversion parts and the second electrode layer. The buffer layer may be formed only the position between the photoelectric conversion parts and the first electrode layer or only the position between the photoelectric conversion parts and the second electrode layer, or both the position between the photoelectric conversion parts and the first electrode layer and the position between the photoelectric conversion parts and the second electrode layer. For example, as shown in FIG. 1B, the buffer layers (6a, 6b, 6c) may be formed between the photoelectric conversion parts (5a, 5b, 5c) and the second electrode layer 8, or as shown in FIG. 9, the buffer layers (7a, 7b, 7c) may be formed between the photoelectric conversion parts (5a, 5b, 5c) and the first electrode layer 3, or as shown in FIG. 10, the buffer layers (6a, 6b, 6c) may be formed between the photoelectric conversion parts (5a, 5b, 5c) and the second electrode layer 8, and the buffer layers (7a, 7b, 7c) may be further formed between the photoelectric conversion parts (5a, 5b, 5c) and the first electrode layer 3.

While each of FIGS. 1B, 9, and 10 shows that the buffer layers are formed on the same side of all types of photoelectric conversion parts, buffer layers may be formed on the same side or different sides depending on the type of the photoelectric conversion part. Although not shown, for example, a buffer layer or layers formed on a type of photoelectric conversion part or parts may be only between the photoelectric conversion parts and the second electrode layer, while a buffer layer or layers formed on any other type or types of photoelectric conversion parts may be only between the photoelectric conversion parts and the first electrode layer.

Assuming that a region having a single photoelectric conversion part is a single solar cell, the buffer layer may be formed depending on the type of the photoelectric conversion part in such a manner that each solar cell can have desired current-voltage characteristics.

Buffer layers may be formed, depending on the type of each photoelectric conversion part, on two or more photoelectric conversion parts. In this case, the buffer layers formed may contain different materials that vary depending on the types of the photoelectric conversion parts, or may have different thicknesses that vary depending on the types of the photoelectric conversion parts. When the buffer layers formed contain different materials that vary depending on the types of the photoelectric conversion parts, the current-voltage characteristics of each solar cell can be controlled based on the difference between the materials of the buffer layers as described above. When the buffer layers formed have different thicknesses that vary depending on the types of the photoelectric conversion parts, the current-voltage characteristics of each solar cell can be controlled based on the difference between the thicknesses of the buffer layers as described above.

When no buffer layer is formed on a type of photoelectric conversion part and when a buffer layer or layers are formed on any other type or types of photoelectric conversion parts, the current-voltage characteristics of the solar cell can be controlled based on the presence or absence of the buffer layer formed as described above.

Assuming that a region having a single photoelectric conversion part is a single solar cell, the current-voltage characteristics of the solar cell can be controlled using a buffer layer or layers in such a manner that current through all solar cells is prevented from flowing in the reverse direction at the operating voltage of the organic thin-film solar cell module applied to a certain external resistance (hereinafter, this control mode is referred to as the “first mode”).

Alternatively, assuming that a region having a single photoelectric conversion part is a single solar cell, the current-voltage characteristics of the solar cell can be controlled using a buffer layer or layers in such a manner that the total output of all solar cells can be higher at the operating voltage of the organic thin-film solar cell module applied to a certain external resistance (hereinafter, this control mode is referred to as the “second mode”).

Hereinafter, each mode is described.

(First Mode of the Control of the Current-Voltage Characteristics of Solar Cell)

In this mode, assuming that a region having a single photoelectric conversion part is a single solar cell, the buffer layer is formed depending on the type of the photoelectric conversion part in such a manner that current through all solar cells is prevented from flowing in the reverse direction at the operating voltage of the organic thin-film solar cell module applied to a certain external resistance.

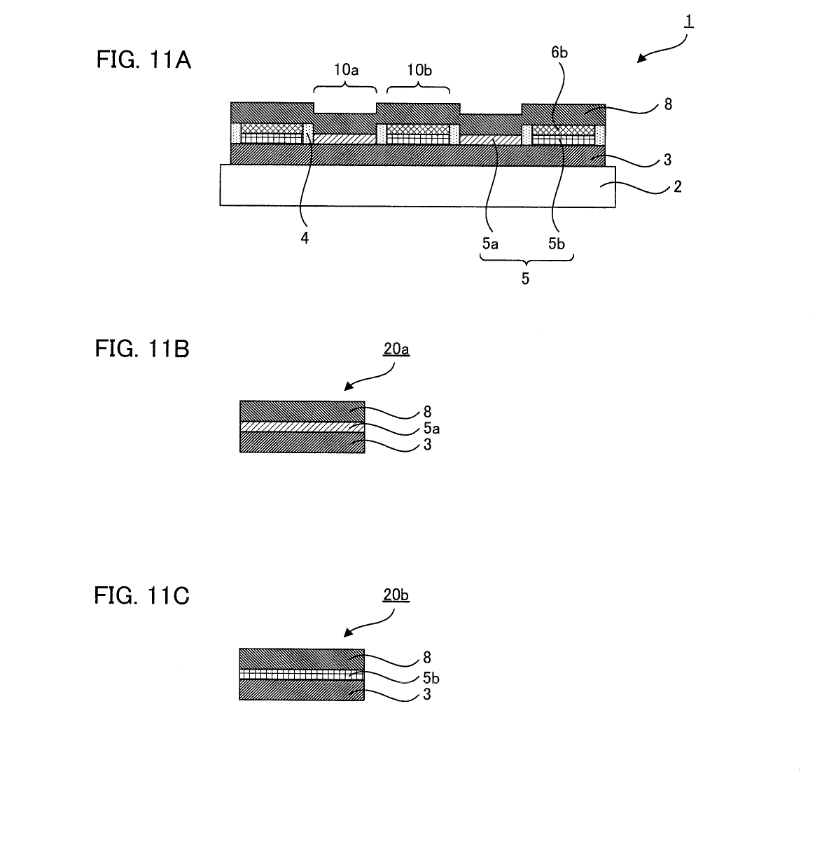

This mode is described with reference to an example as shown in FIG. 11A where the photoelectric conversion layer 5 of an organic thin-film solar cell module 1 has two types of photoelectric conversion parts (5a, 5b) and buffer layers 6b are formed only on second photoelectric conversion parts 5b. In FIG. 11A, a region having a first photoelectric conversion part 5a is called a first solar cell 10a, and another region having a second photoelectric conversion part 5b is called a second solar cell 10b. As shown in FIG. 11B, a structure in which only a first photoelectric conversion part 5a is sandwiched between first and second electrode layers 3 and 8 is called a first reference solar cell 20a, and as shown in FIG. 11C, a structure in which only a second photoelectric conversion part 5b is sandwiched between the first and second electrode layers 3 and 8 is called a second reference solar cell 20b.

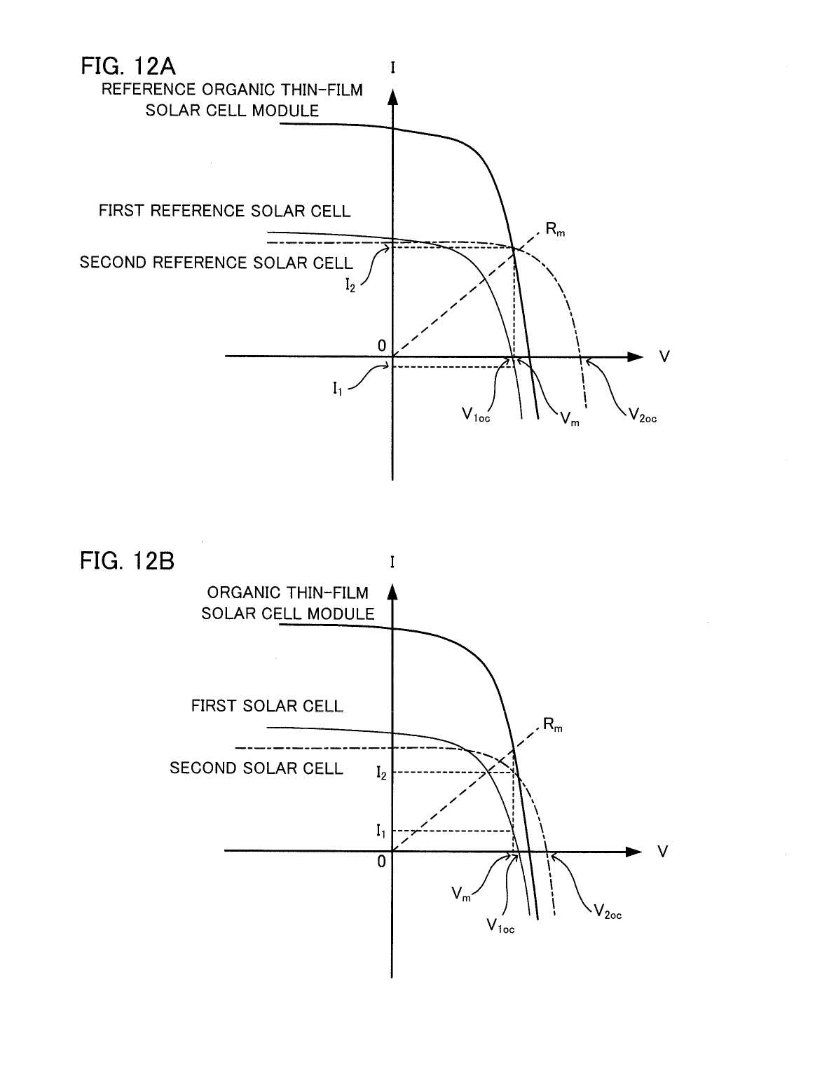

FIG. 12A is a graph showing an example of the current-voltage characteristics of each of the first and second reference solar cells 20a and 20b shown in FIGS. 11B and 11C and an example of the current-voltage characteristics of a reference organic thin-film solar cell module having the first and second reference solar cells 20a and 20b connected in parallel. As shown in FIG. 12A, when the operating voltage Vₘ of the reference organic thin-film solar cell module is applied to a certain external resistance Rₘ, the operating current I₂ flows in the forward direction through the second reference solar cell, but the operating current I₁ flows in the reverse direction through the first reference solar cell.

FIG. 12B is a graph showing an example of the current-voltage characteristics of each of the first and second solar cells 10a and 10b shown in FIG. 11A and an example of the current-voltage characteristics of the organic thin-film solar cell module 1 shown in FIG. 11A. As shown in FIG. 12B, when the operating voltage Vₘ of the organic thin-film solar cell module is applied to a certain external resistance Rₘ, the operating current I₁ flows in the forward direction through the first solar cell, and the operating current I₂ also flow in the forward direction through the second solar cell.

When comparing the second solar cell 10b shown in FIG. 11A to the second reference solar cell 20b shown in FIG. 11C, the second solar cell 10b has the buffer layer 6b formed on the second photoelectric conversion part 5b. As shown in each of FIGS. 12A and 12B, this causes a change from the current-voltage characteristics of the second reference solar cell to those of the second solar cell, resulting in a change from the current-voltage characteristics of the reference organic thin-film solar cell module to those of the organic thin-film solar cell module. Thus, the operating current through all solar cells can be prevented from flowing in the reverse direction.

Thus in this mode, assuming that a region having a single photoelectric conversion part is a single solar cell, a structure in which only a photoelectric conversion part is sandwiched between first and second electrode layers is a reference solar cell, and a structure in which reference solar cells varying with the types of the photoelectric conversion parts are connected in parallel is a reference organic thin-film solar cell module, when the operating current flows in the reverse direction through a certain reference solar cell at the operating voltage of the reference organic thin-film solar cell module applied to a certain external resistance, current through all solar cells can be prevented from flowing in the reverse direction at the operating voltage of the organic thin-film solar cell module applied to a certain external resistance, because the buffer layer is formed depending on the type of the photoelectric conversion part so that the current-voltage characteristic of the solar cell can be controlled.

In some cases, the external resistance for the organic thin-film solar cell module is determined in advance depending on the intended use or application. Thus, it is very useful to control the current-voltage characteristics of solar cells by using buffer layers so that current through all solar cells can be prevented from flowing in the reverse direction at the operating voltage of the organic thin-film solar cell module applied to the external resistance.

If the buffer layers are selected in such a manner that all solar cells have completely the same current-voltage characteristics, current through all solar cells can be prevented from flowing in the reverse direction at the operating voltage of the organic thin-film solar cell module applied to a certain external resistance. However, it seems to be difficult to make the current-voltage characteristics completely the same. Thus, in this mode, the current-voltage characteristics of the solar cells are controlled by selecting the buffer layer in such a manner that current through all solar cells can be prevented from flowing in the reverse direction at the operating voltage of the organic thin-film solar cell module applied to a certain external resistance.

When the operating voltage of the organic thin-film solar cell module is applied to a certain external resistance, current through all solar cells can be prevented from flowing in the reverse direction as described below. As shown in FIG. 12B, the current-voltage characteristics of the solar cells are controlled in such a manner that the operating voltage Vₘ of the organic thin-film solar cell module applied to a certain external resistance Rₘ is lower than the minimum of the open circuit voltages V_{10C} and V_{20C} of the respective solar cells (V_{10C} in this case). As long as the operating voltage of the organic thin-film solar cell module is even a little lower than the minimum of the open circuit voltages of the respective solar cells, the operating current flows in the forward direction through all the solar cells. In contrast, FIG. 12A shows that the operating voltage Vₘ of the reference organic thin-film solar cell module applied to a certain external resistance Rₘ is higher than the open circuit voltage V_{10C} of the first reference solar cell, so that the operating current I₁ can flow in the reverse direction through the first reference solar cell, which exhibits an open circuit voltage V_{10C} lower than the operating voltage Vₘ of the reference organic thin-film solar cell module.

In particular, the current-voltage characteristics of the solar cells are preferably controlled in such a manner that the operating voltage of the organic thin-film solar cell module applied to a certain external resistance is sufficiently lower than the minimum of the open circuit voltages of the respective solar cells. This makes it possible to make the operating current of each solar cell larger.

In this case, the fill factor of the solar cell exhibiting the minimum open circuit voltage may be assumed to be 0.25, which is the minimum solar cell fill factor, and it may be assumed that the operating current of the solar cell exhibiting the minimum open circuit voltage can reach 20% of the short circuit current of the solar cell. Under these assumptions, it is particularly preferred that the operating voltage of the organic thin-film solar cell module is lower than the minimum of the open circuit voltages of the respective solar cells by 20% of the minimum of the open circuit voltages of the respective solar cells. In this case, the operating voltage of the organic thin-film solar cell module applied to a certain external resistance can be made sufficiently lower than the minimum of the open circuit voltages of the respective solar cells, and the operating current of each solar cell can be made larger.

The operating voltage of the organic thin-film solar cell module applied to a certain external resistance can be made lower than the minimum of the open circuit voltages of the respective solar cells by setting the operating voltage of the organic thin-film solar cell module at a low level for the external resistance or by setting the open circuit voltage of the solar cell exhibiting the minimum open circuit voltage at a high level.

To set the operating voltage of the organic thin-film solar cell module at a low level for the external resistance, for example, the open circuit voltage of solar cells other than the solar cell exhibiting the minimum open circuit voltage may be set at a low level.

The current-voltage characteristics (such as the operating voltage, operating current, open circuit voltage, and fill factor) of the solar cells can be determined by a process including making each solar cell for analysis using each type of photoelectric conversion part and measuring the current-voltage characteristics of each solar cell for analysis. For example, the characteristics of the organic thin-film solar cell module 1 shown in FIGS. 1A and 1B can be determined by a process including making each of: a first solar cell for analysis comprising a substrate, and a first electrode layer, a first photoelectric conversion part, a first photoelectric conversion part-specific buffer layer, and a second electrode layer stacked in this order on the substrate; a second solar cell for analysis comprising a substrate, and a first electrode layer, a second photoelectric conversion part, a second photoelectric conversion part-specific buffer layer, and a second electrode layer stacked in this order on the substrate; and a third solar cell for analysis comprising a substrate, and a first electrode layer, a third photoelectric conversion part, a third photoelectric conversion part-specific buffer layer, and a second electrode layer stacked in this order on the substrate; and measuring the current-voltage characteristics of each solar cell for analysis.

The current-voltage characteristics (such as the operating voltage, operating current, open circuit voltage, and fill factor) of the reference solar cells can be determined by a process including using each type of photoelectric conversion part to make each reference solar cell in which only the photoelectric conversion part is sandwiched between first and second electrode layers; and measuring the open circuit voltage of each reference solar cell. For example, the organic thin-film solar cell module 1 shown in FIGS. 1A and 1B can be analyzed by a process including making each of: a first reference solar cell comprising a substrate, and a first electrode layer, a first photoelectric conversion part, and a second electrode layer stacked in this order on the substrate, a second reference solar cell comprising a substrate, and a first electrode layer, a second photoelectric conversion part, and a second electrode layer stacked in this order on the substrate, and a third reference solar cell comprising a substrate, and a first electrode layer, a third photoelectric conversion part, and a second electrode layer stacked in this order on the substrate; and measuring the current-voltage characteristics of each reference solar cell.

(Second Mode of the Control of the Current-Voltage Characteristics of Solar Cell)

In this mode, assuming that a region having a single photoelectric conversion part is a single solar cell, the buffer layer is formed depending on the type of the photoelectric conversion part in such a manner that the total output of all solar cells is high at the operating voltage of the organic thin-film solar cell module applied to a certain external resistance.

This mode is described with reference to an example as shown in FIG. 11A where the photoelectric conversion layer 5 of an organic thin-film solar cell module 1 has two types of photoelectric conversion parts (5a, 5b) and buffer layers 6b are formed only on second photoelectric conversion parts 5b. In FIG. 11R, a region having a first photoelectric conversion part 5a is called a first solar cell 10a, and another region having a second photoelectric conversion part 5b is called a second solar cell 10b. As shown in FIG. 11B, a structure in which only a first photoelectric conversion part 5a is sandwiched between first and second electrode layers 3 and 8 is called a first reference solar cell 20a, and as shown in FIG. 11C, a structure in which only a second photoelectric conversion part 5b is sandwiched between first and second electrode layers 3 and 8 is called a second reference solar cell 20b.

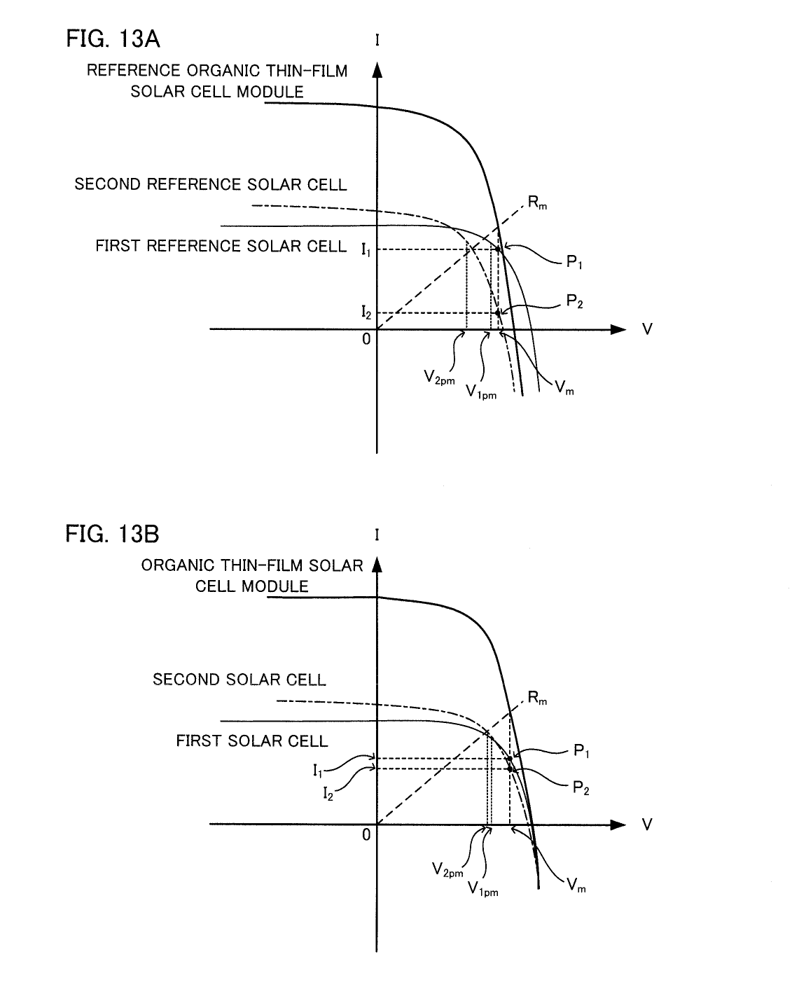

FIG. 13A is a graph showing an example of the current-voltage characteristics of each of the first and second reference solar cells 20a and 20b shown in FIGS. 11B and 11C and an example of the current-voltage characteristics of a reference organic thin-film solar cell module having the first and second reference solar cells 20a and 20b connected in parallel. As shown in FIG. 13A, when the operating voltage Vₘ of the reference organic thin-film solar cell module is applied to a certain external resistance Rₘ, the operating current I₁ through the first reference solar cell is large so that the output is high (see output point P₁ in the drawing), but the operating current I₂ through the second reference solar cell is small so that the output is low (see output point P₂ in the drawing). Thus, the total output of the first and second reference solar cells is low, and the output of the whole of the reference organic thin-film solar cell module is low.

FIG. 13B is a graph showing an example of the current-voltage characteristics of each of the first and second solar cells 10a and 10b shown in FIG. 11A and an example of the current-voltage characteristics of the organic thin-film solar cell module 1 shown in FIG. 11A. As shown in FIG. 13B, when the operating voltage Vₘ of the organic thin-film solar cell module is applied to a certain external resistance Rₘ, the operating current I₁ or I₂ through the first or second solar cell is not small so that the outputs are not low (see output points P₁ and P₂ in the drawing). Thus, the total output of the first and second solar cells is higher than that of the first and second reference solar cells, and the output of the whole of the organic thin-film solar cell module is higher.

When comparing the second solar cell 10b shown in FIG. 11A to the second reference solar cell 20b shown in FIG. 11C, the second solar cell 10b has the buffer layer 6b formed on the second photoelectric conversion part 5b. As shown in FIGS. 13A and 13B, this causes a change from the current-voltage characteristics of the second reference solar cell to those of the second solar cell, resulting in a change from the current-voltage characteristics of the reference organic thin-film solar cell module to those of the organic thin-film solar cell module. Thus, the total output of the first and second solar cells can be made higher than that of the first and second reference solar cells.

In this mode, assuming that a region having a single photoelectric conversion part is a single solar cell, a structure in which only a photoelectric conversion part is sandwiched between first and second electrode layers is a reference solar cell, and a structure in which reference solar cells varying with the types of the photoelectric conversion parts are connected in parallel is a reference organic thin-film solar cell module, the current-voltage characteristics of the solar cell can be controlled by forming the buffer layer depending on the type of the photoelectric conversion part, so that the total output of all solar cells at the operating voltage of the organic thin-film solar cell module applied to an external resistance can be made higher than the total output of all reference solar cells at the operating voltage of the reference organic thin-film solar cell module applied to the external resistance.

In some cases, the external resistance for the organic thin-film solar cell module is determined in advance depending on the intended use or application. Thus, it is very useful to control the current-voltage characteristics of solar cells by using buffer layers so that the total output of all solar cells can be high at the operating voltage of the organic thin-film solar cell module applied to the external resistance.

If the buffer layers are selected in such a manner that all solar cells have completely the same current-voltage characteristics, the total output of all solar cells can be high at the operating voltage of the organic thin-film solar cell module applied to a certain external resistance. However, it seems to be difficult to make the current-voltage characteristics completely the same. Thus, in this mode, the current-voltage characteristics of the solar cells are controlled by selecting the buffer layer in such a manner that the total output of all solar cells can be high at the operating voltage of the organic thin-film solar cell module applied to a certain external resistance.

For example, the total output of all solar cells at the operating voltage of the organic thin-film solar cell module applied to a certain external resistance can be made higher than the total output of all reference solar cells at the operating voltage of the reference organic thin-film solar cell module applied to the external resistance by controlling the current-voltage characteristics of the solar cells in such a manner that the difference between the operating voltage of the organic thin-film solar cell module applied to a certain external resistance and the maximum output operating voltage of the solar cell is smaller than the difference between the operating voltage of the reference organic thin-film solar cell module applied to the external resistance and the maximum output operating voltage of the reference solar cell. In FIGS. 13A and 13B, the current-voltage characteristics of the second solar cell are controlled using the buffer layer in such a manner that the difference between the operating voltage Vₘ of the organic thin-film solar cell module applied to a certain external resistance Rₘ and the maximum output operating voltage V₂ₚₘ of the second solar cell is smaller than the difference between the operating voltage Vₘ of the reference organic thin-film solar cell module applied to the external resistance Rₘ and the maximum output operating voltage V₂ₚₘ of the second reference solar cell, so that the total output of the first and second solar cells is made higher than the total output of the first and second reference solar cells.

In FIGS. 13A and 13B, the difference between the operating voltage Vₘ of the organic thin-film solar cell module applied to a certain external resistance Rₘ and the maximum output operating voltage V₁ₚₘ of the first solar cell is larger than the difference between the operating voltage Vₘ of the reference organic thin-film solar cell module applied to the external resistance Rₘ and the maximum output operating voltage V₁ₚₘ of the first reference solar cell. However, as long as the total output of the first and second solar cells is higher than the total output of the first and second reference solar cells, not only a certain solar cell may be such that the difference between the operating voltage of the organic thin-film solar cell module applied to a certain external resistance and the maximum output operating voltage of the solar cell is smaller than the difference between the operating voltage of the reference organic thin-film solar cell module applied to the external resistance and the maximum output operating voltage of the reference solar cell, but also any other solar cell may be such that the difference between the operating voltage of the organic thin-film solar cell module applied to a certain external resistance and the maximum output operating voltage of the solar cell is larger than the difference between the operating voltage of the reference organic thin-film solar cell module applied to the external resistance and the maximum output operating voltage of the reference solar cell.

In particular, the current-voltage characteristics of each solar cell are preferably controlled in such a manner that the maximum output operating voltage of each solar cell is equal or close to the operating voltage of the organic thin-film solar cell module for a certain external resistance. This makes it possible to make the total output of all solar cells higher.

More specifically, the difference between the maximum and minimum values among the output at the operating voltage of the organic thin-film solar cell module applied to a certain external resistance and the maximum outputs of the respective solar cells is preferably 30% or less, more preferably 20% or less, and in particular, preferably 10% or less of the maximum value. If the difference is in the above range, the total output of all solar cells can be made higher.

The current-voltage characteristics (such as the operating voltage, operating current, open circuit voltage, and fill factor) of the solar cell and the reference solar cell may be measured in the same way as those in the first mode, and a detailed description thereof is omitted herein.

Assuming that a region having a single photoelectric conversion part is a single solar cell, the material for the buffer layer is selected depending on the type of the photoelectric conversion part in such a manner that each solar cell can have desired current-voltage characteristics.

For example, assuming that a region having a single photoelectric conversion part is a single solar cell and a structure in which only a photoelectric conversion part is sandwiched between first and second electrode layers is a reference solar cell, the buffer layer may be made of a material capable of making the open circuit voltage of the solar cell higher than that of the reference solar cell, or made of a material capable of making the open circuit voltage of the solar cell lower than that of the reference solar cell. The buffer layer may also be made of a material capable of making the short circuit current of the solar cell larger than that of the reference solar cell, or made of a material capable of making the short circuit current of the solar cell smaller than that of the reference solar cell. The buffer layer may also be made of a material capable of making the maximum output of the solar cell higher than that of the reference solar cell, or made of a material capable of making the maximum output of the solar cell lower than that of the reference solar cell. These materials are appropriately selected depending on the desired current-voltage characteristics of the solar cell.

The current-voltage characteristics of the solar cells can be controlled as described above.

When a buffer layer is formed on each of two or more types of photoelectric conversion parts, depending on the type of the photoelectric conversion part, the buffer layers for all types of photoelectric conversion parts may be made of materials capable of making the open circuit voltage of the solar cell higher than that of the reference solar cell, or the buffer layers for all types of photoelectric conversion parts may be made of materials capable of making the open circuit voltage of the solar cell lower than that of the reference solar cell. Alternatively, the buffer layer for a type of photoelectric conversion part may be made of a material capable of making the open circuit voltage of the solar cell higher than that of the reference solar cell, and the buffer layer for another type of photoelectric conversion part may be made of a material capable of making the open circuit voltage of the solar cell lower than that of the reference solar cell.

The buffer layers may also be made of materials capable of making the short circuit current of the solar cell larger or smaller than that of the reference solar cell, or made of materials capable of making the maximum output of the solar cell higher or lower than that of the reference solar cell, similarly to the above case using materials capable of making the open circuit voltage of the solar cell higher or lower than that of the reference solar cell.

Particularly when the current-voltage characteristics of the solar cells are controlled in the first mode, the buffer layer preferably contains a material capable of making the open circuit voltage of the solar cell lower than that of the reference solar cell. This is because making the open circuit voltage of the solar cell lower than that of the reference solar cell is easier than making the open circuit voltage of the solar cell higher than that of the reference solar cell, and it makes easy the selection of the material for the buffer layer.

When a buffer layer is formed on each of two or more types of photoelectric conversion parts, depending on the type of the photoelectric conversion part, the buffer layers for all types of photoelectric conversion parts are preferably made of materials capable of making the open circuit voltage of the solar cell lower than that of the reference solar cell. As described above, making the open circuit voltage of the solar cell lower than that of the reference solar cell is easier than making the open circuit voltage of the solar cell higher than that of the reference solar cell, and it makes the selection of the material for the buffer layer easy.

For example, the material capable of making the open circuit voltage of the solar cell lower or higher than that of the reference solar cell may be produced by adjusting the electrical conductivity, work function, or other properties of a material.

More specifically, a buffer layer made of a material with low electrical conductivity may be used to reduce the open circuit voltage of a solar cell. It should be noted that a buffer layer made of a material with high electrical conductivity cannot increase the open circuit voltage of a solar cell.

It is also conceivable that if the difference between the work function of the material of the buffer layer and that of the material of the photoelectric conversion layer is larger than the different between the work function of the material of the electrode layer in contact with the buffer layer and that of the material of the photoelectric conversion layer, the open circuit voltage of the solar cell can be lower than that of the reference solar cell. On the other hand, it is conceivable that if the difference between the work function of the material of the buffer layer and that of the material of the photoelectric conversion layer is smaller than the different between the work function of the material of the electrode layer in contact with the buffer layer and that of the material of the photoelectric conversion layer, the open circuit voltage of the solar cell can be higher than that of the reference solar cell.

Whether the material is capable of making the open circuit voltage of the solar cell higher or lower than that of the reference solar cell can be determined, for example, by measuring the open circuit voltages of the solar cell and the reference solar cell, respectively.

The current-voltage characteristics (such as the operating voltage, operating current, open circuit voltage, and fill factor) of the solar cell and the reference solar cell may be measured as described above, and a detailed description thereof is omitted herein.

The buffer layer may be transparent or nontransparent, and the transparent or nontransparent buffer layer is appropriately selected depending on where the light-receiving surface of the organic thin-film solar cell module and the buffer layer are to be formed. If the light-receiving surface is on the first electrode layer side and if the buffer layer is formed between the photoelectric conversion part and the first electrode layer, the buffer layer should be transparent. Similarly, if the light-receiving surface is on the second electrode layer side and if the buffer layer is formed between the photoelectric conversion part and the second electrode layer, the buffer layer should be transparent. On the other hand, if the light-receiving surface is on the first electrode layer side and if the buffer layer is formed between the photoelectric conversion part and the second electrode layer, the buffer layer may be transparent or nontransparent. Similarly, if the light-receiving surface is on the second electrode layer side and if the buffer layer is formed between the photoelectric conversion part and the first electrode layer, the buffer layer may be transparent or nontransparent. A transparent buffer layer should be used to form a see-through, organic thin-film solar cell module.

The buffer layer may be a hole extraction layer provided between the photoelectric conversion part and a hole extraction electrode, or the buffer layer may be an electron extraction layer provided between the photoelectric conversion part and an electron extraction electrode. Hereinafter, a description is given of the hole extraction layer and the electron extraction layer.

(Hole Extraction Layer)

In the invention, the hole extraction layer is provided to facilitate the extraction of holes from the photoelectric conversion layer to the hole extraction electrode. This increases the efficiency of the extraction of holes from the photoelectric conversion layer to the hole extraction electrode, so that the photoelectric conversion efficiency can be increased.

The material used to form the hole extraction layer is not particularly limited as long as it is capable of stabilizing the extraction of holes from the photoelectric conversion layer to the hole extraction electrode, and such a material may be appropriately selected depending on the type of the photoelectric conversion part as described above. Examples include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron donating compound such as tetrathiofulvalene or tetramethylphenylenediamine and an electron accepting compound such as tetracyanoquinodimethane or tetracyanoethylene. A metal such as Au, In, Ag, or Pd may also be used. The metal may be used alone or in combination with the organic material.

The above material may be mixed with an insulating material to form a material capable of making the open circuit voltage of the solar cell lower than that of the reference solar cell. Examples of such an insulating material include silicon oxide, silicon nitride, or the like.

The hole extraction layer preferably has a thickness in the range of 10 nm to 200 nm, when produced using the organic material, or preferably has a thickness in the range of 0.1 nm to 5 nm, when it is a metal thin film.

The method of forming the hole extraction layer is not particularly limited as long as it is capable of forming the hole extraction layer in a pattern and capable of forming a uniform film with a predetermined thickness. The hole extraction layer may be formed using any of wet and dry processes, which may be appropriately selected depending on material.

(Electron Extraction Layer)

In the invention, the electron extraction layer is provided to facilitate the extraction of electrons from the photoelectric conversion layer to the electron extraction electrode. This increases the efficiency of the extraction of electrons from the photoelectric conversion layer to the electron extraction electrode, so that the photoelectric conversion efficiency can be increased.

The material used to form the electron extraction layer is not particularly limited as long as it is capable of stabilizing the extraction of electrons from the photoelectric conversion layer to the electron extraction electrode, which is appropriately selected depending on the type of the photoelectric conversion part as described above. Examples include inorganic materials such as alkaline-earth metals such as Ca, fluorides of alkali metal or alkaline-earth metal, such as LiF and CaF₂, and metal oxides such as titanium oxide and zinc oxide; electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron donating compound such as tetrathiofulvalene or tetramethylphenylenediamine and an electron accepting compound such as tetracyanoquinodimethane or tetracyanoethylene. A metal-doped layer with an alkali metal or alkaline-earth metal may also be used. Preferred materials include metal-doped layers including bathocuproin (BCP) or bathophenanthron (Bphen) and Li, Cs, Ba, Sr, or the like.

Any of the above materials may be mixed with an insulating material to form a material capable of making the open circuit voltage of the solar cell lower than that of the reference solar cell. The insulating material may be the same as that used for the hole extraction layer.

The method of forming the electron extraction layer is not particularly limited as long as it is capable of forming the electron extraction layer in a pattern and capable of forming a uniform film with a predetermined thickness. The electron extraction layer may be formed using any of wet and dry processes, which may be appropriately selected depending on material.

2. Photoelectric Conversion Layer

In the invention, the photoelectric conversion layer is formed between the first and second electrode layers, formed in a pattern on the first electrode layer, and has different types of photoelectric conversion parts with different absorption wavelength ranges. As used herein, the terms “photoelectric conversion layer” and “photoelectric conversion part” each refers to a component having the function of contributing to the charge separation in the organic thin-film solar cell and transporting the generated electrons and holes to the opposite electrodes, respectively.

The number of the types of photoelectric conversion parts may be two or more. For example, two or three types of photoelectric conversion parts may be provided.

The absorption wavelength ranges of the respective types of photoelectric conversion parts only have to be different, and they may be appropriately selected depending on the arbitrary pattern to be presented by the photoelectric conversion parts.

The arrangement of the photoelectric conversion parts is appropriately selected depending on the arbitrary pattern to be presented by the photoelectric conversion parts. For example, as shown in FIG. 4, the photoelectric conversion parts (5a, 5b, 5c) may be arranged regularly, or as shown in FIG. 7C, the photoelectric conversion parts (5a, 5b) may be arranged irregularly. As shown in FIG. 4, the photoelectric conversion parts (5a, 5b, 5c) may be arranged to show an arbitrary dot pattern, or as shown in FIG. 7C, the photoelectric conversion parts (5a, 5b) may be arranged to show an arbitrary two-dimensional pattern.

When the photoelectric conversion parts are arranged regularly, they may be arranged in a common pixel arrangement pattern, such as a stripe pattern, a mosaic pattern, or a delta pattern.

The size of each photoelectric conversion part is appropriately selected depending on the arbitrary pattern or the like to be presented by the photoelectric conversion parts. For example, if the photoelectric conversion parts are arranged regularly, the photoelectric conversion parts may each have a size of about 0.1 mm square to about 30 mm square. If the photoelectric conversion parts are arranged regularly, if the size of each photoelectric conversion part is small, it may be difficult to form each photoelectric conversion part, and if they are large, it may difficult to show an arbitrary dot pattern.

If the photoelectric conversion parts are arranged regularly, the photoelectric conversion parts may have the same size or different sizes. If photoelectric conversion parts of different sizes are used, shading can be achieved using the different sizes of the photoelectric conversion parts.

The shape of each photoelectric conversion part is appropriately selected depending on the arbitrary pattern or the like to be presented by the photoelectric conversion parts. For example, if the photoelectric conversion parts are regularly arranged, the photoelectric conversion parts may be each in the shape of a rectangular, a polygon, a circular, or any other shape.

The photoelectric conversion part may be a single layer having both an electron accepting function and an electron donating function (a first mode) or a laminate of an electron accepting layer having an electron accepting function and an electron donating layer having an electron donating function (a second mode). Hereinafter, each mode is described.

(1) First Mode of Photoelectric Conversion Part

In the invention, a first mode of the photoelectric conversion part is a single layer having both an electron accepting function and an electron donating function, which contains an electron donating material and an electron accepting material. In this photoelectric conversion part, charge separation is generated based on the p-n junction formed therein, so that it functions by itself.

While such an electron donating material is not particularly limited as long as it has an electron donating function, an electron-donating, conductive, polymer material is particularly preferred.

The conductive polymer is what is called a π-conjugated polymer, which includes a π-conjugated system, in which a carbon-carbon or heteroatom-containing double or triple bond and a single bond are linked alternately, and exhibits semiconducting properties. The conductive polymer material has developed π-conjugation in the main polymer chain and thus is basically advantageous in transporting charges in the main chain direction. In addition, the electron transfer mechanism of the conductive polymer is mainly hopping conduction between π-stacked molecules, and thus, the conductive polymer material is advantageous in transporting charges not only in the main polymer chain direction but also in the thickness direction of the photoelectric conversion part. When a coating liquid including a solution or dispersion of the conductive polymer material in a solvent is used, a film of the conductive polymer material can be easily formed by a wet coating method. Thus, the conductive polymer material is advantageous in that a large-area organic thin-film solar cell module can be produced with it at low cost without the need for expensive equipment.

Examples of the electron-donating, conductive, polymer material include polyphenylene, polyphenylene vinylene, polysilane, polythiophene, polycarbazole, polyvinylcarbazole, porphyrin, polyacetylene, polypyrrole, polyaniline, polyfluorene, polyvinylpyrene, polyvinylanthracene, derivatives thereof, and copolymers thereof, or phthalocyanine-containing polymers, carbazole-containing polymers, and organometallic polymers.

Among the above, preferably used are thiophene-fluorene copolymers, polyalkylthiophene, phenylene ethynylene-phenylene vinylene copolymers, phenylene ethynylene-thiophene copolymers, phenylene ethynylene-fluorene copolymers, fluorene-phenylene vinylene copolymers, and thiophene-phenylene vinylene copolymers. This is because these are appropriately different in energy level from many electron accepting materials.

For example, a detailed method for synthesis of a phenylene ethynylene-phenylene vinylene copolymer (poly[1, 4-phenyleneethynylene-1,4-(2,5-dioctadodecyloxyphen ylene)-1,4-phenyleneethene-1,2-diyl-1,4-(2,5-dioctadodecylo xyphenylene)ethene-1,2-diyl]) is described in Macromolecules, 35, 3825 (2002) or Mcromol. Chem. Phys., 202, 2712 (2001).

While the electron accepting material is not particularly limited as long as it has an electron accepting function, an electron-accepting, conductive, polymer material is particularly preferred. This is because the conductive polymer material has advantages as described above.

Examples of the electron-accepting, conductive, polymer material include polyphenylene vinylene, polyfluorene, derivatives thereof, and copolymers thereof, or carbon nanotubes, fullerene derivatives, CN or CF₃ group-containing polymers, and —CF₃-substituted polymers thereof. Examples of polyphenylene vinylene derivatives include CN-PPV (poly [2-methoxy-5-(2′-ethylhexyloxy)-1,4-(1-cyanovinylene) p henylene]) and MEH-CN-PPV (poly[2-methoxy-5-(2′-ethylhexyloxy)-1,4-(1-cyanovinylene) p henylene]).

An electron accepting material doped with an electron donating compound, an electron donating material doped with an electron accepting compound or the like may also be used. In particular, a conductive polymer material doped with such an electron donating or accepting compound is preferably used. This is because the conductive polymer material has developed π-conjugation in the main polymer chain and thus is basically advantageous in transporting charges in the main chain direction and because charges are produced in the π-conjugated main chain by the doping with an electron donating compound or an electron accepting compound so that the electric conductivity can be significantly increased.

The electron-accepting, conductive, polymer material doped with an electron donating compound includes the above electron-accepting, conductive, polymer material. Examples of the electron donating compound that may be used as a dopant include Lewis bases such as alkali metals and alkaline-earth metals, such as Li, K, Ca, and Cs. Lewis bases act as electron donors.

The electron-donating, conductive, polymer material doped with an electron accepting compound includes the above electron-donating, conductive, polymer material. Examples of the electron accepting compound that may be used as a dopant include Lewis acids such as FeCl₃(III), AlCl₃, AlBr₃, AsF₆, and halogen compounds. Lewis acids act as electron acceptors.

The thickness of the photoelectric conversion part may be that used in a common bulk hetero-j unction organic thin-film solar cell. Specifically, the thickness may be set in the range of 0.2 nm to 3,000 nm, and preferably in the range of 1 nm to 600 nm. If the thickness is more than the above range, the volume resistance of the photoelectric conversion part may increase. If the thickness is less than the above range, the layer may fail to sufficiently absorb light.

The mixing ratio between the electron donating material and the electron accepting material is appropriately adjusted to be optimal depending on the type of the materials used.

The method of forming the photoelectric conversion part is not particularly limited as long as it is capable of forming the photoelectric conversion part in a pattern and capable of forming a uniform film with a predetermined thickness, and any of wet and dry processes may be used. Using a wet process, the photoelectric conversion part can be formed in the air, which reduces cost and makes easy the formation of a large-area product.

In a wet process, the method for applying a coating liquid for forming the photoelectric conversion part is not particularly limited as long as it is capable of forming the photoelectric conversion part in a pattern and capable of uniformly applying the coating liquid for forming the photoelectric conversion part. Examples of such a method include die coating, spin coating, dip coating, roll coating, bead coating, spray coating, bar coating, gravure coating, inkjet process, screen printing, and offset printing.

After the coating liquid for forming the photoelectric conversion part is applied, the coating film formed may be subjected to a drying process. In this case, the solvent and other components in the coating liquid for forming the photoelectric conversion part can be quickly removed so that productivity can be increased.

The drying process may be performed using a common method such as drying by heating, drying by blowing, vacuum drying, or drying by infrared heating.

(2) Second Mode of Photoelectric Conversion Part

In the invention, a second mode of the photoelectric conversion part is a laminate of an electron accepting layer having an electron accepting function and an electron donating layer having an electron donating function. Hereinafter, the electron accepting layer and the electron donating layer are described.

(Electron Accepting Layer)

The electron accepting layer used in this mode has an electron accepting function and contains an electron accepting material.

While the type of such an electron accepting material is not particularly limited as long as it is capable of functioning as an electron acceptor, an electron-accepting, conductive, polymer material is particularly preferred. This is because such a conductive polymer material has advantages as described above. Specifically, the conductive polymer material may be the same as the electron-accepting, conductive, polymer material for use in the first mode of the photoelectric conversion part.

The thickness of the electron accepting layer may be that used in a common bilayer organic thin-film solar cell. Specifically, the thickness may be set in the range of 0.1 nm to 1,500 nm, and preferably in the range of 1 nm to 300 nm. If the thickness is more than the above range, the volume resistance of the electron accepting layer may be high. If the thickness is less than the above range, the layer may fail to sufficiently absorb light.

The electron accepting layer may be formed by the same method as the method of forming the first mode of the photoelectric conversion part.

(Electron Donating Layer)

The electron donating layer used in this mode has an electron donating function and contains an electron donating material.

While the type of such an electron donating material is not limited as long as it is capable of functioning as an electron donor, an electron-donating, conductive, polymer material is particularly preferred. This is because such a conductive polymer material has advantages as described above.

Specifically, the conductive polymer material may be the same as the electron-donating, conductive, polymer material for use in the first mode of the photoelectric conversion part.

The thickness of the electron donating layer may be that used in a common bilayer organic thin-film solar cell. Specifically, the thickness may be set in the range of 0.1 nm to 1,500 nm, and preferably in the range of 1 nm to 300 nm. If the thickness is more than the above range, the volume resistance of the electron donating layer may be high. If the thickness is less than the above range, the layer may fail to sufficiently absorb light.

The electron donating layer may be formed by the same method as the method of forming the first mode of the photoelectric conversion part.

3. Insulating Layer

In the invention, the insulating layer is formed in a pattern between the first and second electrode layers, and also disposed between the photoelectric conversion parts. The insulating layer is provided to insulate the first and second electrode layers from each other.

The type of the material used to form the insulting layer is not particularly limited as long as it has insulating properties and capable of being formed into a patterned insulating layer, which may be a common insulating material. Examples of insulating materials include organic insulating materials such as polyester, an epoxy resin, a melamine resin, a phenolic resin, polyurethane, a silicone resin, polyethylene, polyvinyl chloride, an acrylic resin, and a cardo resin, and inorganic insulating materials such as silicon oxide and silicon nitride.

The insulating layer may be transparent or nontransparent. The insulating layer may also be colored. The transparent or colored insulating layer can further enhance the design characteristics.

The method of forming the insulating layer is not particularly limited as long as it is capable of forming it in a pattern, and any of wet and dry processes may be used. Examples include gravure coating, inkjet printing, offset printing, flexographic printing, and other printing methods, vapor deposition, and photolithography.

The thickness of the insulating layer is not particularly limited as long as it is capable of insulating the first and second electrode layers from each other.

4. First Electrode Layer

In the invention, the first electrode layer is formed all over the substrate. The first electrode layer may be an electrode for extracting holes generated in the photoelectric conversion layer (hole extraction electrode) or an electrode for extracting electrons generated in the photoelectric conversion layer (electron extraction electrode). In general, the first electrode layer forms a hole extraction electrode.

The first electrode layer may be transparent or nontransparent, and the transparent or nontransparent first electrode layer is appropriately selected depending on the light-receiving surface of the organic thin-film solar cell module. If the light-receiving surface is on the first electrode layer side, the first electrode layer should be transparent. On the other hand, if the light-receiving surface is on the second electrode layer side, the first electrode layer may be transparent or nontransparent. A transparent first electrode layer should be used to form a see-through, organic thin-film solar cell module.

If the light-receiving surface is on the second electrode layer side, the first electrode layer may be reflective. This can improve the visibility of the arbitrary pattern presented by the photoelectric conversion parts.

The material for forming first electrode layer is not particularly limited as long as it is the electrically-conductive material. It is preferred that the material for forming the first electrode layer is appropriately selected taking the work function and other characteristics of the material for forming the second electrode layer into account. For example, when the second electrode layer is made of a material with a low work function, the first electrode layer is preferably made of a material with a high work function. Examples of materials with a high work function include Au, Ag, Co, Ni, Pt, C, ITO, SnO₂, fluorine-doped SnO₂, and ZnO. When the first electrode layer is a transparent electrode, the material for forming the first electrode layer is not particularly limited as long as it is the electrically-conductive, transparent material. It may be made of a material commonly used to form a transparent electrode, examples of which include In—Zn—O (IZO), In—Sn—O (ITO), ZnO—Al, and Zn—Sn—O.

When the first electrode layer is a transparent electrode, it preferably has a total light transmittance of 85% or more, more preferably 90% or more, and in particular 92% or more. This is because if the total light transmittance of the first electrode layer is in the above range, light can sufficiently pass through the first electrode layer, so that the photoelectric conversion layer can efficiently absorb light.

The total light transmittance is the value measured in the visible light range using SM Color Computer (model SM-C) manufactured by Suga Test Instruments Co., Ltd.

The first electrode layer may be a single layer or a laminate of materials with different work functions.

The thickness of the first electrode layer, which may be the thickness of a single layer or the total thickness of two or more layers, is preferably in the range of 0.1 nm to 500 nm, and in particular in the range of 1 nm to 300 nm. If the thickness is less than the above range, the first electrode layer may have too high sheet resistance, so that the generated charges may fail to be sufficiently transferred to the external circuit. If the thickness is more than the above range, the total light transmittance may be reduced, so that the photoelectric conversion efficiency may be reduced.

The first electrode layer may be formed using a common electrode-forming method.

5. Second Electrode Layer

In the invention, the second electrode layer is a counter electrode to the first electrode layer, and formed all over so as to cover the photoelectric conversion layer. The second electrode layer may be an electrode for extracting holes generated in the photoelectric conversion layer (hole extraction electrode) or an electrode for extracting electrons generated in the photoelectric conversion layer (electron extraction electrode). In general, the second electrode layer forms an electron extraction electrode.

The second electrode layer may be transparent or nontransparent, and the transparent or nontransparent second electrode layer is appropriately selected depending on the light-receiving surface of the organic thin-film solar cell module. If the light-receiving surface is on the second electrode layer side, the second electrode layer should be transparent. On the other hand, if the light-receiving surface is on the first electrode layer side, the second electrode layer may be transparent or nontransparent. A transparent second electrode layer should be used to form a see-through, organic thin-film solar cell module.

If the light-receiving surface is on the first electrode layer side, the second electrode layer may be reflective. This can improve the visibility of the arbitrary pattern presented by the photoelectric conversion parts.

The material for forming the second electrode layer is not particularly limited as long as it is the electrically-conductive material. It is preferred that the material for forming the second electrode layer is appropriately selected taking the work function and other characteristics of the material for forming the first electrode layer into account. For example, when the first electrode layer is made of a material with a high work function, the second electrode layer is preferably made of a material with a low work function. Specific examples of materials with a low work function include Li, In, Al, Ca, Mg, Sm, Tb, Yb, Zr and LiF. Examples of reflective materials include Al, Ag, Cu and Au.

When the second electrode layer is a transparent electrode, the material for the second electrode layer is not particularly limited as long as it is the electrically-conductive, transparent material. It may be made of a material commonly used to form a transparent electrode.

When the second electrode layer is a transparent electrode, it preferably has a total light transmittance of 85% or more, more preferably 90% or more, and in particular 92% or more. This is because if the total light transmittance of the second electrode layer is in the above range, light can sufficiently pass through the second electrode layer, so that the photoelectric conversion layer can efficiently absorb light.

The total light transmittance may be measured by the same method as described above in the section of the first electrode layer.

The second electrode layer may be a single layer or a laminate of materials with different work functions.

The thickness of the second electrode layer, which may be the thickness of a single layer or the total thickness of two or more layers, is preferably in the range of 0.1 nm to 500 nm, and in particular in the range of 1 nm to 300 nm. If the thickness is less than the above range, the second electrode layer may have too high sheet resistance, so that the generated charges may fail to be sufficiently transferred to the external circuit.

The second electrode layer may be formed using a common electrode-forming method.

6. Substrate

In the invention, the substrate is used to support the first electrode layer, the photoelectric conversion layer, the second electrode layer, the insulating layer, and other components.

The substrate may be transparent or nontransparent, and the transparent or nontransparent substrate is appropriately selected depending on the light-receiving surface of the organic thin-film solar cell module. If the light-receiving surface is on the substrate side, the substrate should be transparent. If the light-receiving surface is on the second electrode layer side, the substrate may be transparent or nontransparent. A transparent substrate should be used to form a see-through, organic thin-film solar cell module.

When the substrate is transparent, the transparent substrate is not particularly limited and can be of any type, such as a non-flexible transparent rigid member such as a quartz glass, PYREX (registered trademark), or synthetic quartz plate or a flexible transparent member such as a transparent resin film or an optical resin plate.

In particular, the transparent substrate is preferably a flexible member such as a transparent resin film. The transparent resin film has good workability, is useful for reducing the manufacturing cost or the weight and for achieving a crack-resistant organic thin-film solar cell module, and can be used in a wide variety of applications including curved surface applications.

V. Colored Layer

In the invention, a colored layer may be formed between the substrate and the first electrode layer, depending on the type of the photoelectric conversion part. This is because the use of the colored layer makes possible an increase in color purity and clear display.

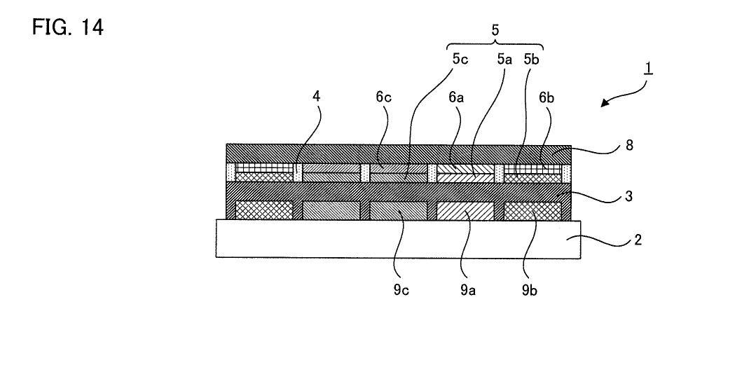

The colored layer or layers should be formed depending on the type of the photoelectric conversion part. Colored layers may be arranged on all types of photoelectric conversion parts. Alternatively, no colored layer may be arranged on a type of photoelectric conversion part, and a colored layer or layers may be arranged on any other type or types of photoelectric conversion parts. If colored layers are arranged on all types of photoelectric conversion parts, color purity can be further increased. For example, FIG. 14 shows that colored layers (9a, 9b, 9c) of different colors are formed between the substrate 2 and the first electrode layer 3 in such a manner that first, second, and third colored layers 9a, 9b, and 9c are arranged on the first, second, and third photoelectric conversion parts 5a, 5b, and 5c, respectively, in which the colors of the colored layers (9a, 9b, 9c) vary depending on the types of photoelectric conversion parts (5a, 5b, 5c).

The color of the colored layer formed on the photoelectric conversion part is appropriately selected depending on the absorption wavelength range of the photoelectric conversion part.

The size, shape, arrangement, and other features of the colored layer formed on the photoelectric conversion part may be the same as those of the photoelectric conversion part.

The colored layer may be the same as a common color filter, and a description thereof is omitted herein.

8. Common Buffer Layer

In the invention, when the buffer layers are formed only on the same side, the same common buffer layers may also be formed on the opposite surfaces of the photoelectric conversion parts, respectively, from the surfaces of the photoelectric conversion parts on which the buffer layers are formed.

All of the common buffer layers on the respective photoelectric conversion parts may be made of the same material, and they may be hole extraction layers or electron extraction layers.

Such hole and electron extraction layers may be the same as those described above in the section of the buffer layer, and a description thereof is omitted herein.

9. Other Features

In addition to the components described above, if necessary, the organic thin-film solar cell module of the invention may have any of the components mentioned below. For example, the organic thin-film solar cell module of the invention may have a functional layer such as a protective sheet, a filler layer, a barrier layer, a protective hard-coat layer, a strength supporting layer, an anti-fouling layer, a high light-reflective layer, a light confining layer, or a sealer layer. A bonding layer may also be formed between the respective functional layers depending on the layered structure.

These functional layers may be the same as those disclosed in publications such as JP 2007-073717 A.

10. Method of Manufacturing Organic Thin-Film Solar Cell Module

A method of manufacturing an organic thin-film solar cell module of the invention is a method of manufacturing an organic thin-film solar cell module comprising a substrate, a first electrode layer formed on the substrate, a photoelectric conversion layer formed in a pattern on the first electrode layer and including different types of photoelectric conversion parts having different absorption wavelength ranges, a second electrode layer formed so as to cover the photoelectric conversion layer, and an insulating layer formed in a pattern between the first and second electrode layers and arranged between the photoelectric conversion parts, characterized in that a buffer layer or buffer layers are formed, depending on the type of the photoelectric conversion part, in at least one of the position between the photoelectric conversion parts and the first electrode layer and the position between the photoelectric conversion parts and the second electrode layer. The method preferably comprises a buffer layer-forming step including selecting a material for the buffer layer depending on the type of the photoelectric conversion part and forming the buffer layer depending on the type of the photoelectric conversion part in such a manner that each solar cell can have desired current-voltage characteristics, assuming that a region having a single photoelectric conversion part is a single solar cell.

In the buffer layer-forming step, the material for the buffer layer is preferably selected depending on the type of the photoelectric conversion part in such a manner that current through all solar cells can be prevented from flowing in the reverse direction at the operating voltage of the organic thin-film solar cell module applied to a certain external resistance.

Alternatively, in the buffer layer-forming step, the material for the buffer layer is preferably selected depending on the type of the photoelectric conversion part in such a manner that the total output of all solar cells can be made higher at the operating voltage of the organic thin-film solar cell module applied to a certain external resistance.

The material and other properties of the buffer layer are described above in detail in the section of the buffer layer, and not described again herein.

The embodiments described above are not intended to limit the scope of the invention. The above embodiments are described by way of example only, and it will be understood that many variations are possible with substantially the same feature as the technical idea recited in the claims to produce the same effect, and all of such variations are within the scope of the invention.

### EXAMPLES

Hereinafter, the invention is more specifically described with reference to the examples.

### Example

(Preparation of Organic Thin-Film Solar Cell Module)

An ITO layer (hole extraction electrode) was formed on a 125 μM thick PET film substrate by sputtering. Subsequently, an epoxy resin was applied in a pattern to the PET film substrate by gravure coating, and cured by heat treatment to form a lattice-patterned insulating layer having openings.

Subsequently, a polythiophene (P3HT: poly(3-hexylthiophene-2,5-diyl)) and C60PCBM ([6,6]-phenyl-C61-butyric acid mettric ester, manufactured by Nano-C, Inc.) were dissolved in bromobenzene to form a coating liquid for forming the first photoelectric conversion part with a solid concentration of 1.4 wt %. Subsequently, the coating liquid for forming the first photoelectric conversion part was applied in a pattern to the PET film substrate by gravure coating, and then dried at 100° C. for 10 minutes to form first photoelectric conversion parts. The first photoelectric conversion parts had an absorption wavelength in the green light range. The first photoelectric conversion parts transmitted red light and looked red. The first photoelectric conversion parts had the same pattern as that of the first photoelectric conversion parts 5a shown in FIG. 4, and each had a size of 12 mm×12 mm.

Subsequently, MDMO-PPV

(poly[2-methoxy-5-(3′,7′-dimethyloctyloxy)-1,4-phenylenevin ylene]) and C60PCBM were dissolved in chlorobenzene to form a coating liquid for forming the second photoelectric conversion part with a solid concentration of 1.4 wt %. Subsequently, the coating liquid for forming the second photoelectric conversion part was applied in a pattern on the PET film substrate by gravure coating, and then dried at 100° C. for 10 minutes to form second photoelectric conversion parts. The second photoelectric conversion parts had an absorption wavelength in the blue light range. The second photoelectric conversion parts transmitted orange light and looked orange. The second photoelectric conversion parts had the same pattern as that of the second photoelectric conversion parts 5b shown in FIG. 4, and each second photoelectric conversion part had the same size as the first photoelectric conversion part.

Subsequently, a fluorene-thiophene copolymer (poly[(9,9-dihexylfluorenyl-2,7-diyl)-co-(bithiophene)]) and C60PCBM were dissolved in chlorobenzene to form a third photoelectric conversion part-forming coating liquid with a solid concentration of 0.5 wt %. Subsequently, the third photoelectric conversion part-forming coating liquid was applied in a pattern on the PET film substrate by gravure coating, and then dried at 100° C. for 10 minutes to form third photoelectric conversion parts. The third photoelectric conversion parts had an absorption wavelength in the violet light range. The third photoelectric conversion parts transmitted yellow light and looked yellow. The third photoelectric conversion parts had the same pattern as that of the third photoelectric conversion parts 5c shown in FIG. 4, and each third photoelectric conversion part had the same size as the first photoelectric conversion part.

Subsequently, first buffer layers including calcium layers were formed on the first photoelectric conversion parts by vacuum deposition using mask patterning. Subsequently, second buffer layers including lithium fluoride layers were formed on the second photoelectric conversion parts by vacuum deposition using mask patterning. Subsequently, third buffer layers including calcium fluoride layers were formed on the third photoelectric conversion parts by vacuum deposition using mask patterning.

Subsequently, an aluminum layer (electron extraction electrode) was formed as a continuous film on all of the buffer layers by vacuum deposition.

(Evaluation of Materials for Buffer Layers)

A first solar cell for analysis was prepared by sequentially depositing the ITO layer, the first photoelectric conversion part, the calcium layer, and the aluminum layer as described above on the substrate. A second solar cell for analysis was prepared by sequentially stacking the ITO layer, the second photoelectric conversion part, the lithium fluoride layer, and the aluminum layer as described above on the substrate. A third solar cell for analysis was also prepared by sequentially stacking the ITO layer, the third photoelectric conversion part, the calcium fluoride layer, and the aluminum layer as described above on the substrate. The open circuit voltage of each solar cell for analysis was measured. As a result, the first, second, and third solar cells for analysis had open circuit voltages of 0.68 V, 0.62 V, and 0.67 V, respectively.

A first reference solar cell was prepared by sequentially depositing the ITO layer, the first photoelectric conversion part, and the aluminum layer as described above on the substrate. A second reference solar cell was prepared by sequentially depositing the ITO layer, the second photoelectric conversion part, and the aluminum layer as described above on the substrate. A third reference solar cell was also prepared by sequentially depositing the ITO layer, the third photoelectric conversion part, and the aluminum layer as described above on the substrate. The open circuit voltage of each reference solar cell was measured. As a result, the first, second, and third reference solar cells had open circuit voltages of 0.70 V, 0.66 V, and 0.95 V, respectively.

The open circuit voltage of each solar cell for analysis was lower than that of the corresponding reference solar cell.

### Comparative Example 1

An organic thin-film solar cell module was prepared as in Example, except that no buffer layers were formed on the first, second, and third photoelectric conversion parts.

### Comparative Example 2

An organic thin-film solar cell module was prepared as in Example, except that calcium layers were formed as buffer layers on all of the first, second, and third photoelectric conversion parts.

[Evaluation]

A continuous operating test was performed on the organic thin-film solar cell modules of Example and Comparative Examples 1 and 2. As a result, the organic thin-film solar cell module of Example operated stably, but the organic thin-film solar cell modules of Comparative Examples 1 and 2 lost the function of the solar cell soon after the start of the operation.

### REFERENCE SIGNS LIST

1: Organic thin-film solar cell module
2: Substrate
3: First electrode layer
4: Insulating layer
5: Photoelectric conversion layer
5a: First photoelectric conversion part
5b: Second photoelectric conversion part
5c: Third photoelectric conversion part
6a, 7a: First photoelectric conversion part-specific buffer layer
6b, 7b: Second photoelectric conversion part-specific buffer layer
6c, 7c: Third photoelectric conversion part-specific buffer layer
8: Second electrode layer
10: Solar cell

1. An organic thin-film solar cell module, comprising:
a substrate;
a first electrode layer formed on the substrate;
a photoelectric conversion layer formed in a pattern on the first electrode layer and including different types of photoelectric conversion parts having different absorption wavelength ranges;
a second electrode layer formed so as to cover the photoelectric conversion layer; and
an insulating layer formed in a pattern between the first electrode layer and the second electrode layer and arranged between the photoelectric conversion parts,
wherein a buffer layer or buffer layers are formed, depending on a type of the photoelectric conversion part, in at least one of a position between the photoelectric conversion parts and the first electrode layer and a position between the photoelectric conversion parts and the second electrode layer.

2. The organic thin-film solar cell module according to claim 1, wherein the buffer layers containing different materials that vary depending on the types of the photoelectric conversion parts are formed.

3. The organic thin-film solar cell module according to claim 1, wherein the buffer layer is not formed on one type of the photoelectric conversion part, and the buffer layer is formed on another type of the photoelectric conversion part.

4. The organic thin-film solar cell module according to any one of claim 1, wherein assuming that a region having one of the photoelectric conversion parts is a single solar cell, the buffer layer contains a material capable of making an open circuit voltage of the solar cell lower than an open circuit voltage of a reference solar cell having only the photoelectric conversion part sandwiched between the first electrode layer and the second electrode layer.
